(19) United States
(12) Patent Application Publication
(10) Pub. No.: US 2015/0311138 A1
(43) Pub. Date: Oct. 29, 2015

(54) TRANSISTORS WITH IMPROVED THERMAL CONDUCTIVITY

(71) Applicant: QUALCOMM Incorporated, San Diego, CA (US)

(72) Inventors: Yong Ju Lee, San Diego, CA (US); Yang Du, Carlsbad, CA (US)

(73) Assignee: QUALCOMM Incorporated, San Diego, CA (US)

(21) Appl. No.: 14/264,229

(22) Filed: Apr. 29, 2014

(51) Int. Cl. H01L 23/373; H01L 29/51; H01L 29/06; H01L 29/78

(52) U.S. Cl. CPC H01L 23/373; H01L 29/785; H01L 29/517; H01L 29/0653

(57) ABSTRACT

Transistors with improved thermal conductivity are disclosed. Portions of the transistor or elements adjacent to the transistor are made from materials that are electrically insulative, but have high thermal conductivities. Increased thermal conductivity provides increased heat dissipation from the transistor, which results in less resistance and less power consumption, which in turns generally improves performance. For example, in a first non-limiting exemplary aspect, the material that can be included for electrical insulation, but having high thermal conductivity for increased heat dissipation is Beryllium Oxide (BeO). In a second non-limiting exemplary aspect, the material that can be included for electrical insulation, but having high thermal conductivity for increased heat dissipation is Aluminum Nitride (AlN).

### BACKGROUND

I. Field of the Disclosure

The technology of the disclosure relates generally to controlling heat within an integrated circuit (IC).

II. Background

Computing devices typically rely on integrated circuits (ICs) composed of many transistors for their underlying functionality. Moore's law indicates that the number of transistors on an IC doubles approximately every two years. The increase in the number of transistors is achieved in part through continued efforts to miniaturize the transistors (i.e., put increasingly more transistors into the same amount of space). As the size of the transistors in the ICs decreases, concerns about leakage current have caused silicon dioxide insulation layers to be used in various locations within the transistors.

While such silicon dioxide insulation layers may effectively reduce leakage current and satisfy other design criteria, silicon dioxide and other insulation layers have generally poor thermal conductivity. In the abstract, such poor thermal conductivity is not necessarily problematic because heat can dissipate over time and within a large enough area, not enough heat can be generated to cause problems. However, as the size of the transistors decreases and the density of the transistors increases, poor thermal conductivity (i.e., high thermal resistance) means that heat becomes trapped in the transistor, which in turn negatively affects the resistance of the transistor, which in turn consumes more power. Greater power consumption results in more generated heat, which is again trapped by the elements with poor thermal conductivity. In extreme cases, the trapped thermal energy may damage the components of the IC. Even when such extreme situations are not reached, the increase in power consumption may negatively shorten battery life or otherwise have undesirable implications.

While the insulative materials in planar transistors have generally poor thermal conductivity, thermal conductivity may be worse in insulative materials employed in three dimensional transistors, such as Fin-based field effect transistors (FinFETs). In FinFETs, the thermal resistance may be an order of magnitude greater than the thermal resistance of a comparable planar transistor. As transistors continue to become smaller, these thermal concerns will continue to grow.

Regardless of whether the FET is a planar transistor or a FinFET, increased performance could be achieved if there were a better way to dissipate heat from within the FET.

### SUMMARY OF THE DISCLOSURE

Aspects disclosed in the detailed description include transistors with improved thermal conductivity. In exemplary aspects, portions of the transistor or elements adjacent to the transistor are made from materials that are electrically insulative, but have high thermal conductivities. Increased thermal conductivity provides increased heat dissipation from the transistor, which results in less resistance and less power consumption, which in turns generally improves performance. For example, in a first non-limiting exemplary aspect, the material that can be included for electrical insulation, but having high thermal conductivity for increased heat dissipation is Beryllium Oxide (BeO). In a second non-limiting exemplary aspect, the material that can be included for electrical insulation, but having high thermal conductivity for increased heat dissipation is Aluminum Nitride (AlN).

In exemplary aspects, the electrically insulative and high thermal conductivity material, such as BeO and AlN, can be provided in one or more components of the transistors to provide increased heat dissipation, which in turn provides improved performance. In this regard, the spacers adjacent the gate may be replaced with such material; the box underneath the body underneath the gate may be replaced with such material; the substrate may be replaced with such material; the shallow trench isolation (STI) adjacent the transistor may be replaced with such material; and/or the high-k buffer layer between the gate and the body may be replaced with such material. While replacing one of these transistor elements with such material aids in dissipating heat, replacing more than one transistor elements with such material may further accelerate heat dissipation.

In this regard, in one aspect, a field effect transistor (FET) is provided. The FET comprises a substrate and a box layer positioned above the substrate. The FET also comprises a body above the box layer forming a channel region between a source and a drain; a gate positioned above the body and a high-k buffer layer between the body and the gate. The FET also comprises a spacer positioned beside the gate; wherein at least one substrate, a portion of the box layer, a portion of the high-k buffer layer, and the spacer is formed from BeO. In this manner, heat dissipation is acceleration resulting in better performance of the transistor.

In another aspect, a FET is provided that comprises a substrate and a box layer positioned above the substrate is disclosed. The FET also comprises a body above the box layer forming a channel region between a source and a drain. The FET also comprises a gate positioned above the body and a high-k buffer layer between the body and the gate. The FET also comprises a spacer positioned beside the gate, wherein at least one of the substrate, a portion of the high-k buffer layer, and the spacer is formed from AlN. In this manner, heat dissipation is acceleration resulting in better performance of the transistor.

In another aspect, a FET assembly is provided. The FET assembly comprises a substrate and a source positioned over the substrate. The FET assembly also comprises a gate and a drain positioned over the substrate and a channel region between the source and the drain. The FET assembly also comprises a shallow trench assembly (STI) positioned proximate either the source or the drain, wherein the STI is formed from either AlN or BeO. In this manner, heat dissipation is acceleration resulting in better performance of the transistor.

In another aspect, a FET is provided that comprises a substrate and a box layer positioned above the substrate is disclosed. The FET also comprises a body above the box layer forming a channel region between a source and a drain and a gate positioned above the body. The FET also comprises a high-k buffer layer between the body and the gate. The FET also comprises a spacer positioned beside the gate, wherein at least one of the substrate, a portion of the box layer, a portion of the high-k buffer layer, and the spacer is formed from a material having a thermal conductivity greater than 200 W/mK and a bandgap voltage greater than 2 electron-volts (eV). In this manner, heat dissipation is acceleration resulting in better performance of the transistor.

In another aspect, a FET is provide that comprises a substrate formed of either BeO or AlN is disclosed. The FET also comprises a box layer positioned above the substrate and a body above the box layer forming a channel region between a source and a drain. The FET also comprises a gate positioned above the body; a high-k buffer layer between the body and the gate and a spacer positioned beside the gate.

In another aspect, a FET is provided that comprises a substrate and a box layer positioned above the substrate, wherein at least a portion of the box layer comprises BeO is disclosed. The FET also comprises a body above the box layer forming a channel region between a source and a drain; a gate positioned above the body; a high-k buffer layer between the body and the gate and a spacer positioned beside the gate. In this manner, heat dissipation is acceleration resulting in better performance of the transistor.

In another aspect, a FET is provided that comprises a substrate and a box layer positioned above the substrate is disclosed. The FET also comprises a body above the box layer forming a channel region between a source and a drain. The FET also comprises a gate positioned above the body with a high-k buffer layer between the body and the gate, wherein at least a portion of the high-k buffer layer comprises either BeO or AlN. A spacer is positioned beside the gate as well. In this manner, heat dissipation is acceleration resulting in better performance of the transistor.

In another aspect, a FET is provided that comprises a substrate and a box layer positioned above the substrate is disclosed. The FET also comprises a body above the box layer forming a channel region between a source and a drain. The FET also comprises a gate positioned above the body and a high-K buffer layer between the body and the gate and a spacer positioned beside the gate, wherein the spacer comprises either BeO or AlN. In this manner, heat dissipation is acceleration resulting in better performance of the transistor.

### BRIEF DESCRIPTION OF THE FIGURES

FIG. 1 is a simplified cross-sectional view of an exemplary conventional field effect transistor (FET) with heat trapped therein;

FIG. 2A is a simplified cross-sectional view of an exemplary FET that includes one or more element comprised from an electrically insulative and high thermal conductive material according to aspects of the present disclosure to improve heat dissipation;

FIG. 2B is the FET of FIG. 2A with exemplary thermal paths illustrated;

FIG. 3A is a simplified cross-sectional view of an exemplary Fin-based FET (FinFET) according to aspects of the present disclosure;

FIG. 3B is a simplified cross-sectional view of a single FinFET from FIG. 3A; and

FIG. 4 is a block diagram of an exemplary processor-based system that can include the transistors of FIGS. 2A-3.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include transistors with improved thermal conductivity. In exemplary aspects, portions of the transistor or elements adjacent to the transistor are made from materials that are electrically insulative, but have high thermal conductivities. Increased thermal conductivity provides increased heat dissipation from the transistor, which results in less resistance and less power consumption, which in turns generally improves performance. For example, in a first non-limiting exemplary aspect, the material that can be included for electrical insulation, but having high thermal conductivity for increased heat dissipation is Beryllium Oxide (BeO). In a second non-limiting exemplary aspect, the material that can be included for electrical insulation, but having high thermal conductivity for increased heat dissipation is Aluminum Nitride (AlN).

In exemplary aspects, the electrically insulative and high thermal conductivity material, such as BeO and AlN, can be provided in one or more components of the transistors to provide increased heat dissipation, which in turn provides improved performance. In this regard, the spacers adjacent the gate may be replaced with such material; the box underneath the body underneath the gate may be replaced with such material; the substrate may be replaced with such material; the shallow trench isolation (STI) adjacent the transistor may be replaced with such material; and/or the high-k buffer layer between the gate and the body may be replaced with such material. While replacing one of these transistor elements with such material aids in dissipating heat, replacing more than one transistor elements with such material may further accelerate heat dissipation.

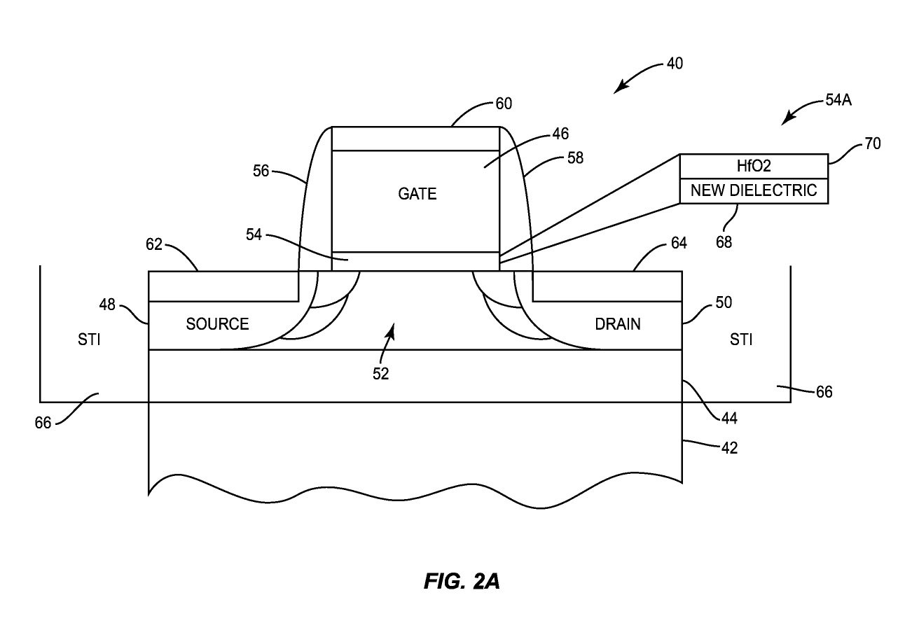

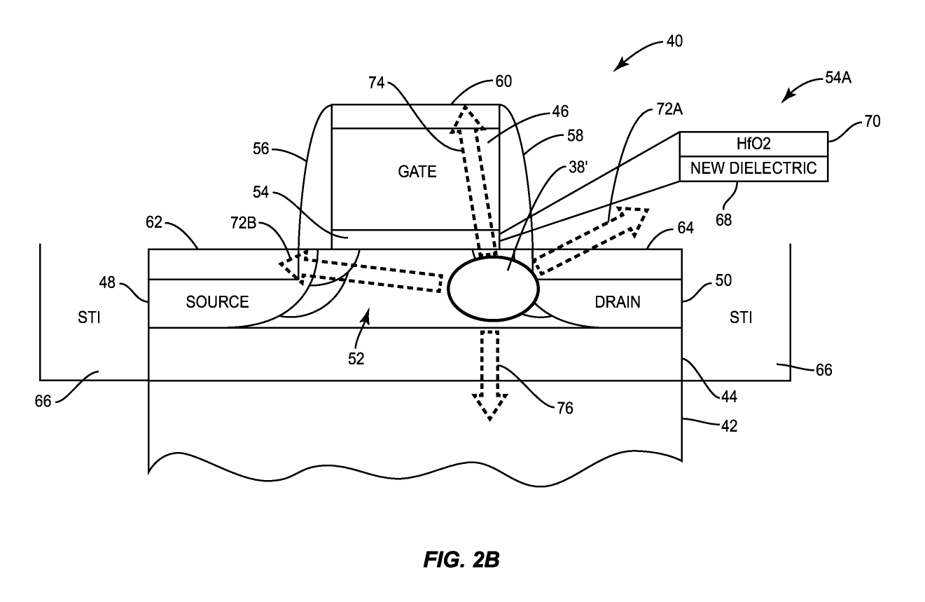

Before addressing particulars of exemplary aspects of the present disclosure, a brief overview of a conventional transistor is provided with reference to a field effect transistor (FET). Aspects of the present disclosure are discussed below beginning with reference to FIG. 2A.

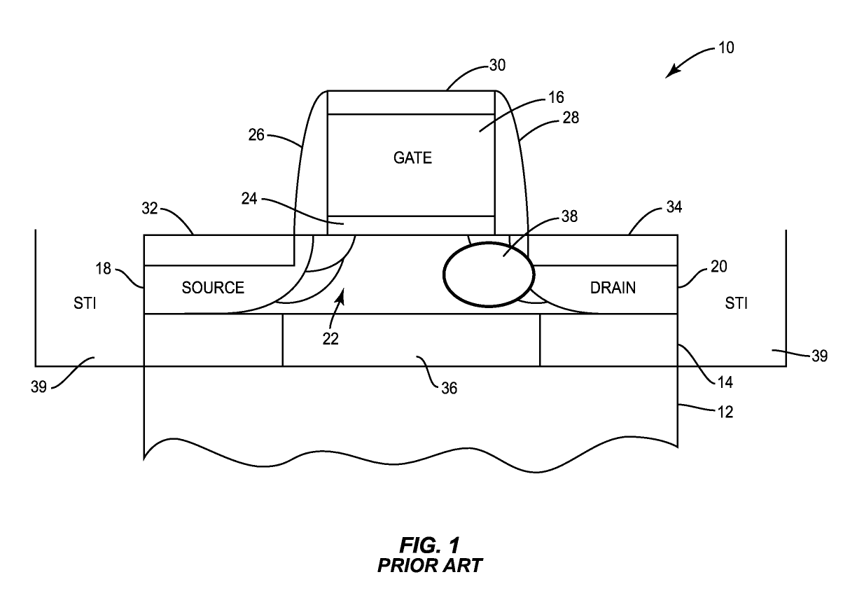

In this regard, FIG. 1 is a conventional silicon on insulator (SOI) FET 10. The FET 10 may include (or, more properly, be positioned above) a substrate 12, which may be a material such as silicon (Si). Above the substrate 12, an insulator 14 may be positioned. The insulator 14 may be Silicon Dioxide (SiO₂), sapphire, or other comparable material. The FET 10 further includes a gate 16, a source 18, and a drain 20. The gate 16, source 18, and drain 20 may be formed from materials such as n or p doped silicon. The source 18 and the drain 20 are positioned above the insulator 14 and have a channel region 22 therebetween. The channel region 22 is typically formed from a material such as silicon, although it may be doped as desired. The insulator 14 is used to reduce leakage current between the source 18 and drain 20 (e.g., outside the channel region 22). The gate 16 is separated from the channel region 22 by a high-k dielectric buffer region 24. Spacers 26, 28 may be positioned on either side of the gate 16. The spacers 26, 28 are typically formed from insulator materials such as SiO₂ or Silicon Nitride (SiN). Silicide contacts 30, 32, 34 may provide electrodes for the gate 16, source 18, and drain 20 respectively. In some aspects, the insulator 14 may include a box region 36 which has the insulator material and the rest of the insulator 14 is silicon. On either side of the FET 10 may be a shallow trench isolation (STI) region 39. The STI is typically made from SiO₂.

With continued reference to FIG. 1, the materials of a typical FET 10 are not selected for thermal conductivity. By way of example, bulk silicon (e.g., where both the box region 36 and the substrate 12 are silicon), may have a thermal conductivity of approximately 120 W/mK. The body that contains channel region 22 is made of silicon and may have a thermal conductivity of approximately 10-30 W/mK. SiO₂ has a relatively low thermal conductivity of 1.4 W/mK. As a result, heat generated within the FET 10 is essentially trapped within the body as stylistically represented by thermal bloom 38. Thermal bloom 38 negatively impacts performance of the FET 10 by increasing the resistance of the FET 10, which in turn results in increased power consumption. In extreme cases, such trapped heat may damage the FET 10. While the problems of trapped heat exist in planar FETs, it should be appreciated that the problems are exacerbated within a Fin-based FET (FinFET) where thermal conductivities are generally about 20 W/mK.

To help improve thermal conductivity such that the thermal bloom 38 is dissipated before it can negatively impact performance, aspects of the present disclosure replace one or more insulative materials in the FET 10 with materials having relatively high thermal conductivities (i.e., greater than 200 W/mK) and acceptable insulative or dielectric properties (e.g., a band gap voltage greater than 1.2 eV). In exemplary aspects, the materials selected are BeO and/or AlN. BeO has a thermal conductivity of approximately 330 W/mK and AlN has a thermal conductivity of approximately 285 W/mK. Recent study shows that it is possible to epitaxially grow AlN and BeO on silicon, making the use of these materials practical. An exemplary study shows a lattice mismatch of approximately 0.7%, which is considered to be within acceptable tolerances for manufacturing purposes.

In this regard, FIG. 2A illustrates a FET 40 according to an exemplary aspect of the present disclosure. FET 40 may include (or, more properly, be positioned above) a substrate 42. Above the substrate 42, a box 44 may be positioned. The FET 40 further includes a gate 46, a source 48, and a drain 50. The gate 46, source 48, and drain 50 may be formed from materials such as n or p doped silicon. The source 48 and the drain 50 are positioned above the box 44 and have a channel region 52 therebetween. The channel region 52 is typically formed from a material such as silicon, although it may be doped as desired. The gate 46 is separated from the channel region 52 by a high-k dielectric buffer region 54. High-k dielectric buffer region 54 may be formed from two layers as shown by the inset 54A. Spacers 56, 58 may be positioned on either side of the gate 46. Silicide contacts 60, 62, 64 may provide electrodes for the gate 46, source 48, and drain 50 respectively. STI regions 66 may exist to either side of the FET 40.

With continued reference to FIG. 2A, various elements of the FET 40 may be replaced with a thermally conductive insulator material such as BeO or MN. In exemplary aspects, one or more of the substrate 42, the box 44, the spacers 56, 58, STI regions 66, or a portion of the high-k dielectric buffer region 54 may be so replaced. For the high-k dielectric buffer region 54, the lower layer 68 may be so replaced while the upper layer 70 may remain a conventional material such as Hafnium Oxide (HfO₂). If multiple areas are replaced with the thermally conductive insulator material, heat is dissipated more readily, but improvements are seen even with a single replacement.

In this regard, FIG. 2B illustrates thermal paths created by material replacement according to exemplary aspects of the present disclosure. In particular, if the spacers 56, 58 are replaced, the thermal bloom 38′ may travel upwardly and/or outwardly as indicated by arrows 72A, 72B. If the lower layer 68 is replaced, the thermal bloom 38′ may travel upwardly through the gate 46 as indicated by arrow 74. If both the spacers 56, 58 and the lower layer 68 are replaced, the heat may travel through the lower layer 68 to the spacers 56, 58 and radiate upwardly and outwardly. If the box 44 is replaced, the thermal bloom 38′ may be dissipated downwardly as indicated by arrow 76. Likewise, if the STI regions 66 are replaced, heat that passes through the source 48 and drain 50 may sink into the STI regions 66. If both the box 44 and the STI regions 66 are replaced, heat may pass through the box 44 to the STI regions 66, providing even faster heat dissipation. If the box 44 and the substrate 42 are replaced, heat may readily dissipate downwardly.

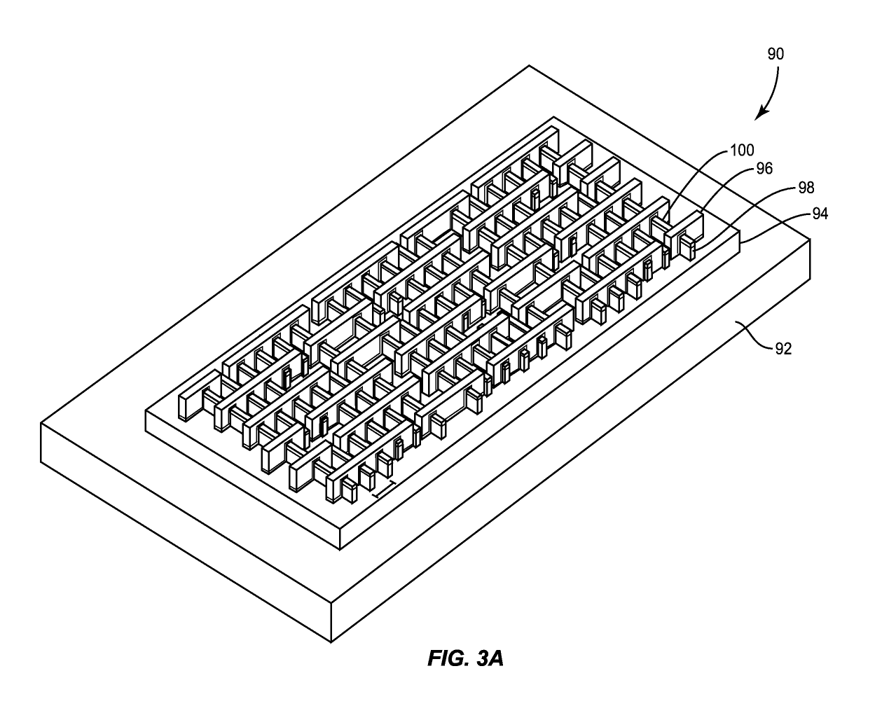

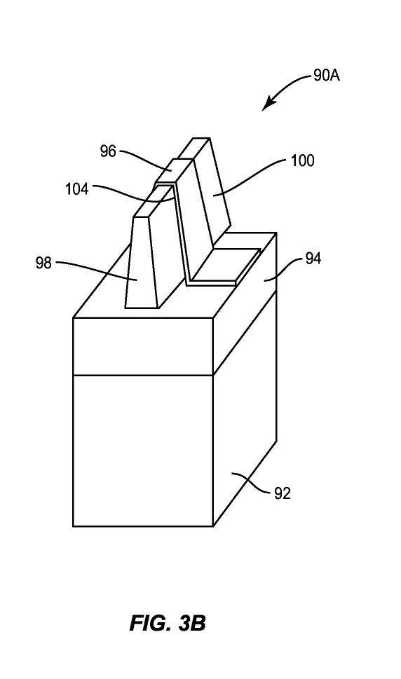

While heat dissipation is improved in planar FETs such as FET 40, heat dissipation is even more dramatic in a FinFET, such as those illustrated in FIGS. 3A and 3B. In particular, FIG. 3A illustrates a plurality of FinFETs 90 and FIG. 3B illustrates a single FinFET 90A. The FinFET 90 may include (or, more properly, be positioned above) a substrate 92, which may be a material such as silicon (Si). Above the substrate 92, an insulator 94 may be positioned. The FinFET 90 further includes a gate 96, a source 98, and a drain 100. The gate 96, source 98, and drain 100 may be formed from materials such as n or p doped silicon. The source 98 and the drain 100 are positioned above the insulator 94 and have a channel region therebetween and under the gate 96. The channel region is typically formed from a material such as silicon, although it may be doped as desired. The gate 96 is separated from the channel region by a high-k dielectric buffer region 104.

In an exemplary embodiment, the insulator 94, a box below the channel region, spacers (not shown), a portion of the high-k dielectric buffer region 104, or a plurality of these elements may be replaced by BeO or AlN as described above to improve the heat dissipating characteristics of the FinFET 90.

Note further that aspects of the present disclosure may replace one element with AlN and another element with BeO. Likewise, other materials may be used that have similar characteristics such as having a thermal conductivity greater than 200 W/mK and/or a band gap greater than 1.2 eV.

The transistors with improved thermal conductivity according to aspects disclosed herein may be provided in or integrated into any processor-based device. Examples, without limitation, include a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

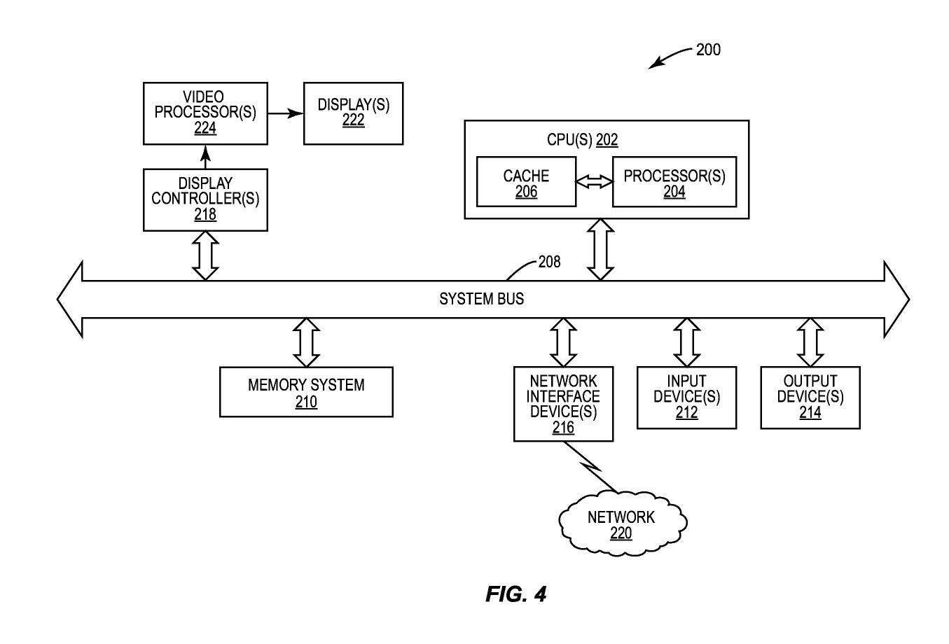

In this regard, FIG. 4 illustrates an example of a processor-based system 200 that can employ the FET 40 or FinFET 90 illustrated in FIGS. 2A-3. In this example, the processor-based system 200 includes one or more central processing units (CPUs) 202, each including one or more processors 204. The CPU(s) 202 may have cache memory 206 coupled to the processor(s) 204 for rapid access to temporarily stored data. The CPU(s) 202 is coupled to a system bus 208 and can intercouple devices included in the processor-based system 200. As is well known, the CPU(s) 202 communicates with these other devices by exchanging address, control, and data information over the system bus 208. For example, the CPU(s) 202 can communicate bus transaction requests to the memory system 210. Although not illustrated in FIG. 4, multiple system buses 208 could be provided.

Other devices can be connected to the system bus 208. As illustrated in FIG. 4, these devices can include one or more input devices 212, one or more output devices 214, one or more network interface devices 216, and one or more display controllers 218, as examples. The input device(s) 212 can include any type of input device, including but not limited to input keys, switches, voice processors, etc. The output device(s) 214 can include any type of output device, including but not limited to audio, video, other visual indicators, etc. The network interface device(s) 216 can be any devices configured to allow exchange of data to and from a network 220. The network # can be any type of network, including but not limited to a wired or wireless network, private or public network, a local area network (LAN), a wide local area network (WLAN), and the Internet. The network interface device(s) 216 can be configured to support any type of communication protocol desired.

The CPU(s) 202 may also be configured to access the display controller(s) 218 over the system bus 208 to control information sent to one or more displays 222. The display controller(s) 218 sends information to the display(s) 222 to be displayed via one or more video processors 224, which process the information to be displayed into a format suitable for the display(s) 222. The display(s) 222 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

1. A field effect transistor (FET), comprising:
a substrate;
a box layer positioned above the substrate;
a body above the box layer forming a channel region between a source and a drain;
a gate positioned above the body;
a high-k buffer layer between the body and the gate; and
a spacer positioned beside the gate;
wherein at least one of the substrate, a portion of the box layer, and a portion of the high-k buffer layer is formed from Beryllium Oxide (BeO).

2. The FET of claim 1, further comprising a shallow trench isolation (STI) positioned adjacent either the source or the drain.

3. The FET of claim 2, wherein the STI is formed from either BeO or Aluminum Nitride (AlN).

4. The FET of claim 1, wherein more than one of the substrate, the portion of the box layer, and the portion of the high-k buffer layer, are formed from BeO.

5. The FET of claim 1, wherein in addition to
the at least one of the substrate, the portion of the box layer, and the portion of the high-k buffer layer, formed from BeO,
another one of the substrate, the portion of the box layer, the portion of the high-k buffer layer, and the spacer are formed from Aluminum Nitride (AlN).

6. The FET of claim 1 integrated into an integrated circuit (IC).

7. The FET of claim 1, wherein the FET comprises a Fin-based FET (FinFET).

8. The FET of claim 1, wherein a second portion of the high-k buffer layer comprises Hafnium Oxide (HfO₂).

9. A field effect transistor (FET), comprising:
a substrate;
a box layer positioned above the substrate;
a body above the box layer forming a channel region between a source and a drain;
a gate positioned above the body;
a high-k buffer layer between the body and the gate; and
a spacer positioned beside the gate;
wherein at least one of the substrate and the spacer is formed from Aluminum Nitride (AlN).

10. The FET of claim 9, further comprising a shallow trench isolation (STI) positioned adjacent either the source or the drain.

11. The FET of claim 10, wherein the STI is formed from either Beryllium Oxide (BeO) or AlN.

12. The FET of claim 9, wherein more than one of the substrate, a portion of the box layer, a portion of the high-k buffer layer, and the spacer are formed from AlN.

13. The FET of claim 9, wherein in addition to
the at least one of the substrate and the spacer formed from AlN,
another one of the substrate, a portion of the box layer, a portion of the high-k buffer layer, and the spacer are formed from Beryllium Oxide (BeO).

14. The FET of claim 9, wherein the FET is a Fin-based FET (FinFET).

15. The FET of claim 9, wherein a second portion of the high-k buffer layer comprises Hafnium Oxide (HfO₂).

16. A field effect transistor (FET) assembly, comprising:
a substrate;
a source positioned over the substrate;
a gate positioned over the substrate;
a drain positioned over the substrate;
a channel region between the source and drain; and
a shallow trench isolation (STI) positioned proximate either the source or the drain, wherein the STI is formed from Beryllium Oxide (BeO).

17. The FET assembly of claim 16, wherein the FET is a Fin-based FET (FinFET).

18. A field effect transistor (FET), comprising:
a substrate;
a box layer positioned above the substrate;
a body above the box layer forming a channel region between a source and a drain;
a gate positioned above the body;
a high-k buffer layer between the body and the gate; and
a spacer positioned beside the gate;
wherein at least one of the substrate, a portion of the box layer, and a portion of the high-k buffer layer is formed from a material having a thermal conductivity greater than 200 W/mK and a bandgap voltage greater than 2 eV.

19. A field effect transistor (FET), comprising:
a substrate formed of either Beryllium Oxide (BeO) or Aluminum Nitride (AlN);
a box layer positioned above the substrate;
a body above the box layer forming a channel region between a source and a drain;
a gate positioned above the body;
a high-k buffer layer between the body and the gate; and
a spacer positioned beside the gate.

20. A field effect transistor (FET), comprising:
a substrate;
a box layer positioned above the substrate, wherein at least a portion of the box layer comprises Beryllium Oxide (BeO);
a body above the box layer forming a channel region between a source and a drain;
a gate positioned above the body;
a high-k buffer layer between the body and the gate; and
a spacer positioned beside the gate.

21. A field effect transistor (FET), comprising:
a substrate;
a box layer positioned above the substrate;
a body above the box layer forming a channel region between a source and a drain;
a gate positioned above the body;
a high-k buffer layer between the body and the gate, wherein at least a portion of the high-k buffer layer comprises either Beryllium Oxide (BeO) or Aluminum Nitride (AlN); and
a spacer positioned beside the gate.

22. A field effect transistor (FET), comprising:
a substrate;
a box layer positioned above the substrate;
a body above the box layer forming a channel region between a source and a drain;
a gate positioned above the body;
a high-k buffer layer between the body and the gate; and
a spacer positioned beside the gate, wherein the spacer comprises Aluminum Nitride (AlN).
